(19) United States
(12) Patent Application Publication
(10) Pub. No.: US 2016/0043321 A1
(43) Pub. Date: Feb. 11, 2016

(54) OPTICAL MASK AND LASER TRANSFER METHOD USING THE SAME

(71) Applicant: Samsung Display Co., Ltd., Yongin-city (KR)

(72) Inventor: Young Gil KWON, Suwon-si (KR)

(21) Appl. No.: 14/622,007

(22) Filed: Feb. 13, 2015

(30) Foreign Application Priority Data
Aug. 7, 2014 (KR) 10-2014-0101779

(51) Int. Cl. H01L 51/00; H01L 27/32

(52) U.S. Cl. CPC H01L 51/0013; H01L 27/3244

(57) ABSTRACT

An optical mask according to exemplary embodiments of the present invention may comprise: a light transmittance variable layer to be in a transparent state when thermal energy is generated and to be in an opaque state when the thermal energy dissipates; and a heat generation layer disposed on a surface of the light transmittance variable layer and generates the thermal energy.

### CROSS-REFERENCE TO RELATED APPLICATION

This application claims priority from and the benefit of Korean Patent Application No. 10-2014-0101779, filed on Aug. 7, 2014, which is incorporated herein by reference for all purposes as if fully set forth herein.

### BACKGROUND

1. Field

Exemplary embodiments of the present invention relate to an optical mask including a light transmittance variable layer and a laser transfer method using the optical mask. The optical mask may include a heat generation layer disposed on a surface of a light transmittance variable layer and makes the opaque light transmittance variable layer transparent, and a laser transfer method which may increase transfer selectivity by forming transmitting windows in some regions of the light transmittance variable layer by radiating laser light only to some regions of the optical mask.

2. Discussion of the Background

An organic electroluminescent device may include an anode, a cathode, and organic layers interposed between the anode and the cathode. The organic layers include at least an organic light-emitting layer and may further include a hole injection layer, a hole transport layer, an electron transport layer, and an electron injection layer. The organic electroluminescent device is classified as a polymer organic electroluminescent device or a low molecular weight organic electroluminescent device according to the material that forms the organic light-emitting layer.

To implement a full-color organic electroluminescent device, the organic light-emitting layer should be patterned. Specifically, an organic light-emitting layer in a low molecular weight organic electroluminescent device may be patterned using a fine metal mask, and an organic light-emitting layer in a polymer organic electroluminescent device may be patterned using an inkjet printing method or a laser induced thermal imaging (LITI) method. In particular, the LITI method has the advantage of finely patterning the above organic layer. Also, the LITI method is a dry process, whereas the inkjet printing method is a wet process.

Forming a polymer organic layer pattern using the LITI method requires at least a light source and organic electroluminescent device substrates, i.e., a device substrate and a donor substrate. The donor substrate consists of a base film, a light-to-heat conversion layer, and a transfer layer composed of one or more organic layers. Patterning the organic layers of the donor substrate on the device substrate may be achieved when light emitted from the light source is absorbed and converted into thermal energy by the light-to-heat conversion layer of the donor substrate and then the organic layers of the transfer layer are transferred onto the device substrate by the thermal energy.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments of the present invention provide an optical mask which may provide high transfer selectivity and high contrast, and a laser transfer method using the optical mask.

However, aspects of the present invention are not restricted to the one set forth herein. The above and other aspects of the present invention will become more apparent to one of ordinary skill in the art to which the present invention pertains by referencing the detailed description of the present invention given below.

Additional aspects will be set forth in the detailed description which follows, and, in part, will be apparent from the disclosure, or may be learned by practice of the inventive concept.

According to an exemplary embodiment of the present invention, an optical mask may comprise: a light transmittance variable layer to be in a transparent state when thermal energy is generated and to be in an opaque state when the thermal energy dissipates; and a heat generation layer disposed on a surface of the light transmittance variable layer and generates the thermal energy.

The optical mask may further comprise discontinuous bank patterns on the light-to-heat conversion layer, wherein the light-to-heat conversion layer is exposed between the discontinuous bank patterns.

According an exemplary embodiment of the present invention, an optical mask may comprise: a first absorption layer configured to convert light energy into thermal energy; a light transmittance variable layer disposed on the first absorption layer, to be in a transparent state when thermal energy is generated and to be in an opaque state when the thermal energy dissipates; and a second absorption layer disposed on the light transmittance variable layer and configured to convert light energy transmitted through the light transmittance variable layer into the thermal energy, wherein the second absorption layer is thicker than the first absorption layer.

According to exemplary embodiment of the present invention, a laser transfer method may comprise: radiating light to transfer at least some of organic matter of a transfer layer to a target substrate; converting at least some of energy of the radiated light transmitted through a light-to-heat conversion layer disposed on a first surface of a light transmittance variable layer to a thermal energy; generating the thermal energy by a heat generation layer disposed on a second surface of the light transmittance variable layer; and converting the light transmittance variable layer to a transparent state by the generated thermal energy, the light transmittance variable layer configured to be in an opaque state when the thermal energy dissipates, wherein the transfer layer is disposed on the light-to-heat conversion layer.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept

The above and other aspects and features of the present invention will become more apparent by describing in more detail exemplary embodiments thereof with reference to the attached drawings.

FIG. 1 is a mimetic exploded perspective view of an organic light-emitting display device according to an exemplary embodiment of the present invention.

FIG. 2 is a mimetic cross-sectional view taken along the line II-II′ of FIG. 1.

FIG. 3 is a circuit diagram of a pixel of a display panel illustrated in FIG. 1.

FIG. 4 is a mimetic partial enlarged cross-sectional view of the display panel illustrated in FIG. 1.

FIG. 5 is a mimetic cross-sectional view of an optical mask according to an exemplary embodiment of the present invention.

FIGS. 6 and 7 are views mimetically illustrating a process of forming an organic layer on a transistor substrate of the organic light-emitting display device using an optical mask according to an exemplary embodiment of the present invention.

FIG. 8 is a mimetic cross-sectional view of an optical mask according to an exemplary embodiment of the present invention.

FIGS. 9 and 10 are views mimetically illustrating a process of forming an organic layer on a transistor substrate using an optical mask according to an exemplary embodiment of the present invention.

FIG. 11 is a mimetic cross-sectional view of an optical mask according to an exemplary embodiment of the present invention.

FIGS. 12 and 13 are views mimetically illustrating a process of forming an organic layer on a transistor substrate using the optical mask according to an exemplary embodiment of the present invention.

FIG. 14 is a mimetic cross-sectional view of an optical mask according to an exemplary embodiment of the present invention.

FIGS. 15 and 16 are views mimetically illustrating a process of forming an organic layer on a transistor substrate using the optical mask according to an exemplary embodiment of the present invention.

FIG. 17 is a mimetic cross-sectional view of an optical mask according to an exemplary embodiment of the present invention.

FIGS. 18 and 19 are views mimetically illustrating a process of forming an organic layer on a transistor substrate using an optical mask according to an exemplary embodiment of the present invention.

FIG. 20 is a mimetic cross-sectional view of an optical mask according to an exemplary embodiment of the present invention.

FIGS. 21 and 22 are views mimetically illustrating a process of forming an organic layer on a transistor substrate using an optical mask according to an exemplary embodiment of the present invention.

### DETAILED DESCRIPTION OF THE ILLUSTRATED EMBODIMENTS

Features of the inventive concept and methods of accomplishing the same may be understood more readily by reference to the following detailed description of preferred embodiments and the accompanying drawings. The inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art, and the inventive concept will only be defined by the appended claims.

In the drawings, the thickness of layers and regions are exaggerated for clarity. It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically, electrically and/or fluidly connected to each other.

Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the invention.

Spatially relative terms, such as “below,” “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” relative to other elements or features would then be oriented “above” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Exemplary embodiments will hereinafter be described with reference to the accompanying drawings.

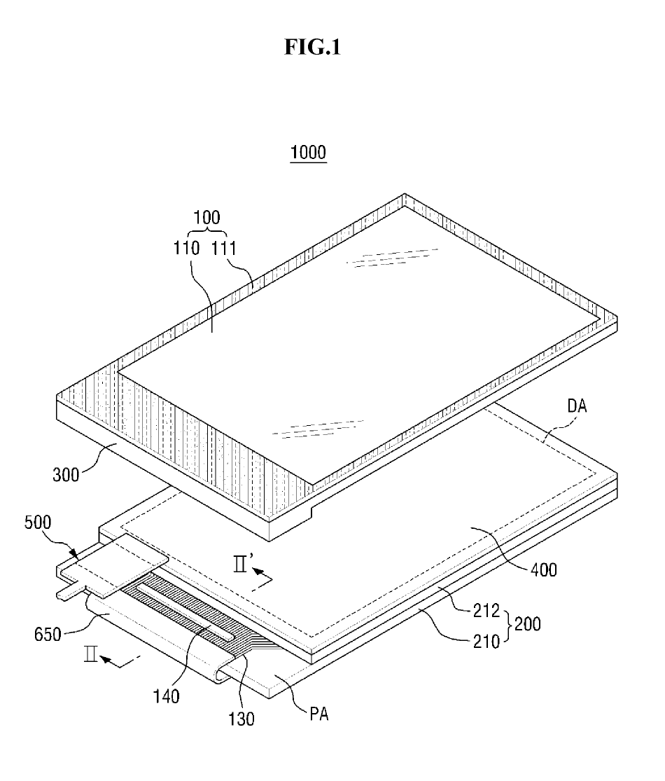

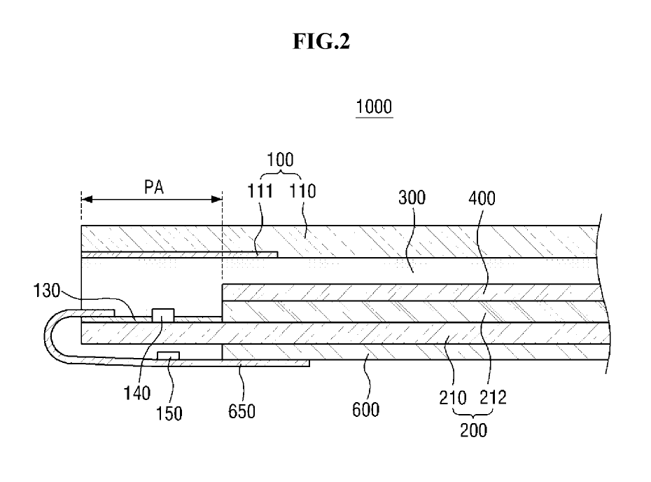

FIG. 1 is a mimetic exploded perspective view of an organic light-emitting display device according to an exemplary embodiment of the present invention. FIG. 2 is a mimetic cross-sectional view taken along the line II-IF of FIG. 1.

Referring to FIGS. 1 and 2, the organic light-emitting display device 1000 may include a display panel 200 which displays an image, a cover window 100 which is located on an outer side of a display surface of the display panel 200, and a resin layer 300 which is located between the display panel 200 and the cover window 100. In addition, the organic light-emitting display device 1000 may include a touch screen panel 400 which may be attached to or disposed on the display surface of the display panel 200 and a touch screen circuit film 500 which is connected to the touch screen panel 400.

The display panel 200 may include a substrate 210 which has a display area DA and a pad area PA, and an encapsulation substrate 212 which may be bonded or disposed onto the substrate 210. The substrate 210 and the encapsulation substrate 212 may be made of, for example, a glass or polymer film, but is not limited thereto. A plurality of signal lines (including at least scan lines and data lines) and a plurality of pixels may be located in the display area DA of the substrate 210, and a plurality of metal wiring lines 130 connected to the signal lines may be located in the pad area PA.

The display panel 200 may include a first integrated circuit (IC) chip 140 mounted on the pad area PA using, for example, a chip-on-glass (COG) method. The first IC chip 140 may include any one of a scan driver and a data driver. The scan driver may supply scan signals to the pixels via the scan lines, and the data driver may supply data signals to the pixels via the data lines.

The encapsulation substrate 212 may be smaller than the substrate 210 and may be attached to the display area DA of the substrate 210. The substrate 210 and the encapsulation substrate 212 may be integrally bonded with each other by a sealant (not illustrated) coated along edges of the encapsulation substrate 212. The encapsulation substrate 212 may protect the pixels from outside air containing moisture and oxygen by sealing the pixels. In addition, a thin-film encapsulation layer may be formed instead of the encapsulation substrate 212 by alternately stacking one organic layer and one inorganic layer at least once.

The organic light-emitting display device 1000 may include a printed circuit board (PCB) 600 which may include a control circuit to transmit a control signal to the display panel 200, and a main circuit film 650 which may connect the display panel 200 and the PCB 600. The main circuit film 650 may be attached to or disposed on the pad area PA to be electrically connected to the metal wiring lines 130. Further, the main circuit film 650 may be bent toward an opposite side to the display surface of the display panel 200 such that the PCB 600 may be located on the opposite side of the display surface of the display panel 200.

One of the scan driver and the data driver may be mounted on the main circuit film 650 using, for example, a chip-on-film (COF) method. The first IC chip 150 may be one of the scan driver and the data driver which is mounted on the main circuit film 650 using the COF method.

The pixels of the substrate 210 may emit light toward the encapsulation substrate 212, and an outer surface of the encapsulation substrate 212 may be the display surface of the display panel 200. The touch screen panel 400 may be attached to or disposed on the outer surface of the encapsulation substrate 212 and may overlap with the display area DA. The touch screen circuit film 500 may be electrically connected to electrodes of the touch screen panel 400. The touch screen circuit film 500 may be located above the pad area PA.

The cover window 100 may be located on the outer side of the display surface of the display panel 200 to protect the display panel 200 from external impact and scratches. The cover window 100 may be made of a transparent material such as glass or transparent plastic and cover both the encapsulation substrate 212 and the pad area PA. The cover window 100 may include a light-transmitting portion 110, which may correspond to the display area DA and a light-blocking portion 111 which is located around the edge of the light-transmitting portion 110. The light-blocking portion 111 may block a portion of the display panel 200 on which no image may be displayed.

The resin layer 300 may be located between the display panel 200 and the cover window 100 to bond the display panel 200 and the cover window 100 together. More specifically, the resin layer 300 may fill the whole or part of a space between the touch screen panel 400 and the cover window 100, and the whole or part of a space between the pad area PA and the cover window 100. When the resin layer 300 is formed to have the same area as the substrate 210, and completely fills the space between the display panel 200 and the cover window 100, bonding performance may be increased.

The resin layer 300 may include acrylic resin that is cured by ultraviolet light. The resin layer 300 may initially be coated on the cover window 100 in, for example, a liquid or paste state. After the display panel 200 and the cover window 100 are stacked, the resin layer 300 may be cured by ultraviolet light

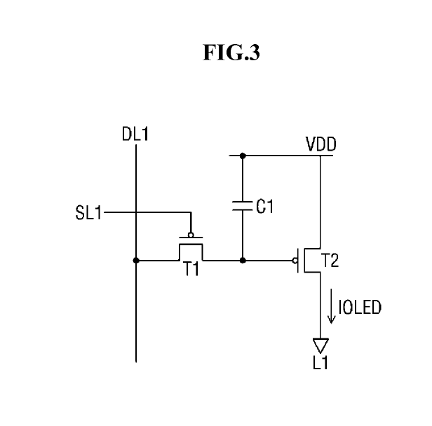

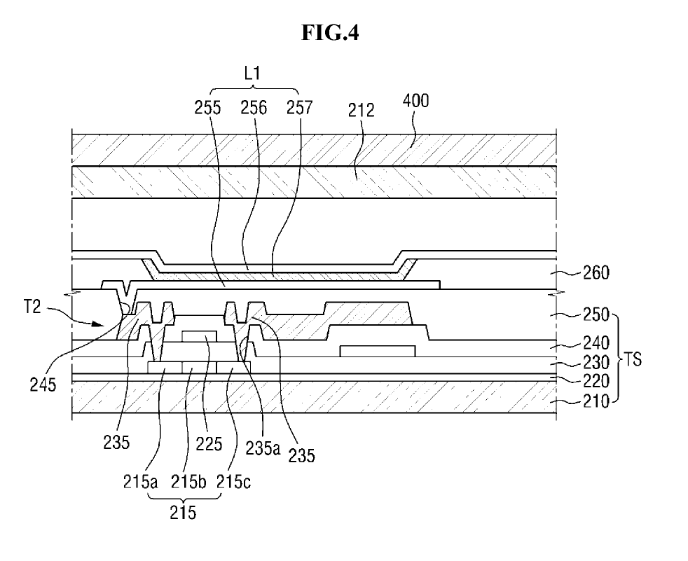

FIG. 3 is a circuit diagram of a pixel of the display panel illustrated in FIG. 1. FIG. 4 is a mimetic partial enlarged cross-sectional view of the display panel illustrated in FIG. 1.

Referring to FIGS. 3 and 4, a pixel may include an organic light-emitting diode (OLED) L1 and a driving circuit unit. The OLED L1 may include a pixel electrode 255, an organic light-emitting layer 257, and a common electrode 256. The driving circuit unit may include at least two thin-film transistors (e.g., a switching transistor T1 and a driving transistor T2) and at least one capacitor C1.

Any one of the pixel electrode 255 and the common electrode 256 may be an electron injection electrode, and the other one of the pixel electrode 255 and the common electrode 256 may be a hole injection electrode. Electrons and holes injected into the organic light-emitting layer 255 may be combined in the organic light-emitting layer 255 to generate excitons. As the excitons generate energy, the organic light-emitting layer 257 may emit light.

The switching transistor T1 is connected to a scan line SL1 and a data line DL1. Further, the switching transistor T1 may apply a data voltage received through the data line DL1 to the driving transistor T2 according to a switching voltage input to the scan line SL1. The capacitor C1 is connected to the switching transistor T1 and a power source line VDD. The capacitor C1 may store a voltage corresponding to a difference between a voltage received from the switching transistor T1 and a voltage supplied from the power source line VDD.

The driving transistor T2 is connected to the power source line VDD and the capacitor C1 to supply an output current IOLED, which may be proportional to the square of a difference between the voltage stored in the capacitor C1 and a threshold voltage, to the OLED L1. Accordingly, the OLED L1 may emit light at an intensity proportional to the output current IOLED.

As illustrated in FIG. 4, the driving transistor T2 may include a semiconductor layer 215, a gate electrode 225, and source/drain electrodes 235. The pixel electrode 255 may be connected to the drain electrode 235 of the driving transistor T2. The pixel electrode 255 may be made of a metal layer which reflects light, and the common electrode 256 may be made of a transparent conductive layer which transmits light. Light generated by the organic light-emitting layer 257 may be reflected by the pixel electrode 255 and may be transmitted through the common electrode 256 and the encapsulation substrate 212 to emerge out of the display panel 200.

Referring to FIG. 4, the display panel 200 may include the substrate 210, the semiconductor layer 215, a buffer layer 220, the gate electrode 225, a gate insulating layer 230, the source/drain electrodes 235, an interlayer insulating film 240, a planarization layer 250, a pixel defining layer 260, and the encapsulation substrate 212. The touch screen panel 400 may be disposed on the encapsulation substrate 212.

The buffer layer 220 may be formed or disposed on the substrate 210. The buffer layer 220 may be made of, for example, a silicon nitride layer, a silicon oxide layer, a silicon oxynitride layer, or a multilayer of the same, but is not limited thereto.

The semiconductor layer 215 may be formed by depositing amorphous silicon on the buffer layer 220 and then patterning and crystallizing the amorphous silicon.

The gate insulating layer 230 may be formed or disposed on the semiconductor layer 215.

The gate electrode 225 may be formed or disposed on the gate insulating layer 230 in a region corresponding to the semiconductor layer 215. The gate insulating layer 230 may be made of, for example, a silicon nitride layer, a silicon oxide layer, a silicon oxynitride layer, or a multilayer of the same, but is not limited thereto. A source region 215c and a drain region 215a may be formed by injecting conductive impurities into the semiconductor layer 215 using the gate electrode 225 as a mask. A channel region 215b may be a region defined between the source/drain regions 215a and 215c, as shown in FIG. 4.

The interlayer insulating film 240 may be formed or disposed on the gate electrode 225 and over the entire surface of the substrate 210. The interlayer insulating film 240 may be made of, for example, a silicon nitride layer, a silicon oxide layer, a silicon oxynitride layer, or a multilayer of the same, but is not limited thereto.

Contact holes 235a may be formed to penetrate through the gate insulating layer 230 and the interlayer insulating film 240. The contact holes 235a may expose the source/drain regions 215a and 215c, respectively.

The source/drain electrodes 235 may be formed or disposed by stacking a conductive layer on the substrate 210 having the contact holes 235a and patterning the conductive layer. The source/drain electrodes 235 are connected to the source/drain regions 215a and 215c by the contact holes 235a.

The planarization layer 250 may be formed or disposed on the source/drain electrodes 235 and over the entire or part of the surface of the substrate 210. The planarization layer 250 may be made of one type of material selected from a group consisting polyimide, benzocyclobutene series resin, and acrylate, but is not limited thereto.

A via hole 245 may be formed in the planarization layer 250 to expose one of the source/drain electrodes 235. The source/drain electrodes 235 which is exposed by the via hole 245 may be connected to the pixel electrode 255 formed on the planarization layer 250.

The pixel electrode 255 may be made of, for example, indium tin oxide (ITO) or indium zinc oxide (IZO) having a high work function. The pixel electrode 255 may include a reflective layer made of a metal having high reflectivity, such as Al, Al—Nd, or Ag, but is not limited thereto. If the organic light-emitting display device 1000 is a bottom emission type, the pixel electrode 255 may not include the reflective layer but may be made of ITO or IZO which may be a transparent conductive layer.

The pixel defining layer 260 is formed or disposed on the pixel electrode 255, and an opening may be formed in the pixel defining layer 260 by patterning the pixel defining layer 260. The pixel defining layer 250 may define the pixels. The pixel defining layer 250 may be made of one type of material selected from a group consisting of polyimide, benzocyclobutene series resin, and acrylate, but is not limited thereto.

The pixel circuit illustrated in FIG. 3 and the cross-sectional structure of the display panel 200 illustrated in FIG. 4 are examples only, and the organic light-emitting display device 1000 is not limited to the above example and may be modified in various ways.

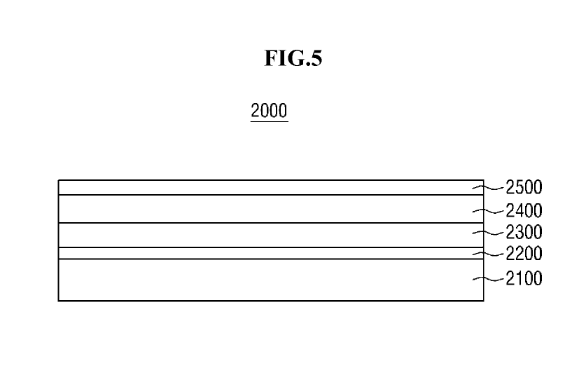

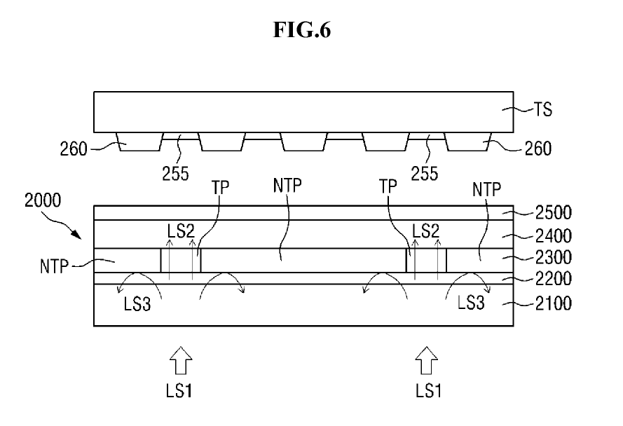

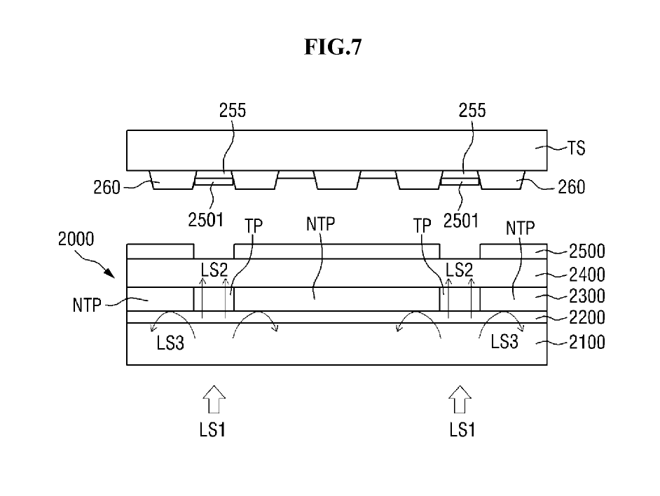

FIG. 5 is a mimetic cross-sectional view of an optical mask according to an exemplary embodiment of the present invention. FIGS. 6 and 7 are views mimetically illustrating a process of forming an organic layer on a transistor substrate of a organic light-emitting display device using an optical mask according to an exemplary embodiment of the present invention.

Referring to FIG. 5, an optical mask 2000 may include a base substrate 2100, a first absorption layer 2200, a light transmittance variable layer 2300, a second absorption layer 2400, and a transfer layer 2500.

The base substrate 2100 may be a light-transmitting substrate through which lamp light or laser light may be transmitted. The base substrate 2100 may be any substrate that has light-transmitting properties. For example, the base substrate 2100 may be a glass substrate, a quartz substrate, or a synthetic resin substrate made of a transparent polymer material having high light-transmitting properties, such as polyester, polyacryl, polyepoxy, polyethylene, polyethylene terephthalate, etc. Lamp light or laser light that passes through the base substrate 2100 may reach the first absorption layer 2200 and generate heat in the first absorption layer 2200.

The first absorption layer 2200 may absorb light of an infrared-visible light region that passes through the base substrate 2100 and may convert the absorbed light into thermal energy. The first absorption layer 2200 may have a small thickness with a light transmittance rate of 90% or more. For example, the first absorption layer 2200 may absorb 10% of the light and may generate thermal energy using the absorbed light.

The first absorption layer 2200 may be made of a metal material having a high absorption rate, such as molybdenum (Mo), chrome (Cr), titanium (Ti), tin (Sn), tungsten (W) or an alloy of the same. For example, when a laser beam having a wavelength of approximately 800 nm is to be radiated, the first absorption layer 2200 may be made of a metal (such as Cr or Mo) having a relatively low reflectivity and a relatively high melting point, but aspects of the present invention are not limited thereto. The first absorption layer 2200 may absorb lamp light or laser light and generate thermal energy which changes the light transmittance variable layer 2300 to be transparent using the absorbed light.

The first absorption layer 2200 may be formed using various methods such as, for example, a sputtering method, an electron beam deposition method, and a vacuum deposition method.

The light transmittance rate of the light transmittance variable layer 2300 may be reversibly changed by thermal energy generated from the first absorption layer 2200. For example, the light transmittance variable layer 2300 may be opaque at a room temperature of approximately 18 to 25° C. and may not transmit much light. However, the light transmittance variable layer 2300 may become more transparent when the first absorption layer 2200 reaches a critical temperature or may gradually become transparent as the temperature rises. This reversible change in light transmittance rate may be periodically repeated according to the supply of thermal energy. The light transmittance variable layer 2300 may show a reversible thermal bleaching phenomenon.

The light transmittance variable layer 2300 may be made of a material that becomes more transparent or gradually becomes transparent at a critical temperature or temperature range to reach a critical light transmittance rate at the critical temperature or temperature range. The critical temperature range may be, for example, approximately 30° C. to 150° C., approximately 40° C. to 140° C., or approximately 50° C. to 130° C. The critical light transmittance rate may be, for example, approximately 70% to less than 100%, or approximately 80% to 90%.

The material that forms the light transmittance variable layer 2300 is not limited to a particular material. For example, the light transmittance variable layer 2300 may include paraffin wax. Since the melting point of paraffin wax is 53° C., paraffin wax may become a transparent liquid phase at the melting point or above. When the temperature of the first absorption layer 2200 is 55° C., the light transmittance variable layer 2300 may have a light transmittance rate of 80%. The light transmittance variable layer 2300 may be formed by, for example, coating a mixture of paraffin wax, polydimethylsiloxane and dodecane on the first absorption layer 2200, and then drying the mixture at a temperature of 60° C. Since the melting point of paraffin wax is 53° C. as described above, the phase of paraffin wax may be changed to a transparent liquid phase in the drying process, and the melted paraffin wax may form a homogeneous state by swelling a matrix of polydimethylsiloxane. As a result, the light transmittance variable layer 2300 may show a light transmittance rate of 80% or more. Light transmittance rate is in direction proportion to the content of paraffin wax. Therefore, an increase in the content of paraffin wax leads to an increase in light transmittance rate.

The second absorption layer 2400 may absorb light of an infrared-visible light region that passes through the base substrate 2100 and may convert the absorbed light into thermal energy. The second absorption layer 2400 may be thicker than the first absorption layer 2200. The second absorption layer 2400 may be formed in a thickness that may convert substantially some or all of transmitted light into thermal energy. The absorption rate of the second absorption layer 2400 may be increased by adjusting light transmittance rate by adjusting the thickness of the second absorption layer 2400.

Similar to the first absorption layer 2200, the second absorption layer 2400 may be made of a metal material having a high absorption rate, such as molybdenum (Mo), chrome (Cr), titanium (Ti), tin (Sn), tungsten (W) or an alloy of the same, but aspects of the invention are not limited thereto.

Like the first absorption layer 2200, the second absorption layer 2400 may be formed using various methods such as, for example, a sputtering method, an electron beam deposition method, and a vacuum deposition method.

The transfer layer 2500 may include organic material layers included in the organic light-emitting display device 1000, such as, for example, an organic light-emitting layer (EML), a hole injection layer (HIL), a hole transport layer (HTL), an electron injection layer (EIL), and an electron transport layer (ETL). The transfer layer 2500 may have a single layer structure including one of the organic material layers or a multilayer structure including two or more of the organic material layers.

In addition, the transfer layer 2500 may be formed using various methods including a wet method and a dry method. Examples of the wet method may include a spin coat method, a spray coat method, an inkjet method, a deep coat method, a cast method, a die coat method, a roll coat method, a blade coat method, a bar coat method, a gravure coat method, and a print method. In addition, examples of the dry method may include a vacuum deposition method and a sputtering method. However, aspects of the invention are not limited thereto.

When the wet method is used to form the transfer layer 2500, a solution or a dispersing liquid may be adjusted by dissolving or dispersing a desired deposition material in a solvent. The solvent may be any solvent that may dissolve or disperse the deposition material without reacting with the deposition material. Examples of the solvent include a halogen solvent such as chloroform, tetrachloromethane, dichloromethane, 1,2-dichloroethane or chlorobenzene; an aromatic solvent such as acetone, methyl ethyl ketone, diethyl ketone, n-propyl methyl ketone or cyclohexanone; an ester solvent such as ethyl acetate, n-propyl acetate, n-butyl acetate, ethyl propionate, γ-butyrolactone or dimethyl carbonate; an ether solvent such as tetrahydrofuran or dioxane; an amide solvent such as dimethylformamide or dimethylacetamide; dimethyl sulfoxide, hexane, and water. A mixture of multiple types of the above solvents may also be used. The wet method may increase the efficiency of material use and reduce manufacturing costs.

The transfer layer 2500 may not be even. For example, the transfer layer 2500 may be shaped like a fine island or a layer having protrusions and depressions.

Referring to FIGS. 6 and 7, transmitting windows TP may be formed in the light transmittance variable layer 2300 by selectively radiating the light transmittance variable layer 2300 with laser light LS1. The laser light LS1 may be transmitted through the base substrate 2100 to reach the first absorption layer 2200. The first absorption layer 2200 may increase the transmittance of the light transmittance variable layer 2300 by absorbing the laser light LS1. As described above, the first absorption layer 2200 may generate thermal energy sufficient to increase the light transmittance rate of the light transmittance variable layer 2300. Therefore, the first absorption layer 2200 may not absorb the whole of the laser light LS1, and the first absorption layer 2200 may absorb a portion of the laser light LS1 which may generate thermal energy sufficient to form the transmission windows TP in the light transmittance variable layer 2300.

For example, the first absorption layer 2200 may absorb approximately 5 to 10% of the laser light LS1. Here, approximately 5 to 10% of the laser light LS1 is a numerical representation of the amount of light that may generate heat sufficient to make the light transmittance variable layer 2300 transparent. The absorption rate of the first absorption layer 2200 is not limited to the above range.

By selectively radiating the light transmittance variable layer 2300 with the laser light LS1, the transmitting windows TP may be formed only in regions of the light transmittance conversion layer 2300 which generate thermal energy by absorbing part of the laser light LS1. For example, the transmitting windows TP may be formed only in regions radiated with the laser light LS1, and non-transmitting windows NTP may be formed in regions other than the regions radiated with the laser light LS1. The non-transmitting windows NTP may reflect the laser light LS1 to produce laser light LS3, and the transmitting windows TP may transmit the laser light LS1 to produce laser light LS2.

The laser light LS1 may have substantially a Gaussian profile. A relatively high thermal energy is concentrated in a convex central region of the Gaussian profile. Therefore, a transmitting window TP may be instantaneously formed in the light transmittance variable layer 2300. While the thermal energy is gradually reduced in regions on both sides of the central region of the Gaussian profile. Therefore, these regions have a relatively lower thermal energy than the central region. As a result, no transmitting window TP may be formed in the light transmittance variable layer 2300. For example, one or more regions of the laser light LS1, which may correspond to Gaussian tails may be blocked by the non-transmitting windows NTP, and thus, may fail to reach the second absorption layer 2400. Since the one or more regions of the laser light LS1 which may correspond to the Gaussian tails may not form the transmitting windows TP in the light transmittance variable layer 2300, the laser light LS2 may have a rectangular profile with a uniform distribution of thermal energy.

The laser light LS2 that transmits through the light transmittance variable layer 2300 may reach the second absorption layer 2400, and the second absorption layer 2400 may generate thermal energy sufficient to transfer the transfer layer 2500 to the transistor substrate TS by absorbing a reference amount of the laser light LS2. In an example, the reference amount of the laser light LS2 may be substantially all of the laser light LS2. A temperature suitable for transferring the transfer layer 2500 may range, but is not limited to, 200° C. to 300° C.

The transfer layer 2500 may be selectively transferred to the transistor substrate TS when supplied with thermal energy from the second absorption layer 2400. For example, organic matter (e.g., the organic layer 2501) may be transferred to the pixel electrode 255 between portions of the pixel defining layer 260 of the transistor substrate TS.

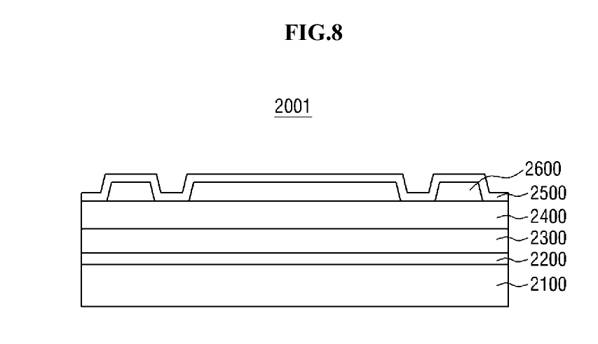

FIG. 8 is a mimetic cross-sectional view of an optical mask according to an exemplary embodiment of the present invention.

Referring to FIG. 8, the optical mask 2001 may further include a bank layer 2600. The optical mask 2001 is different from the optical mask 2000 of FIG. 5 in that it further includes the patterned bank layer 2600.

The bank layer 2600 may guide organic matter of a transfer layer 2500 to be sublimated by thermal energy generated from a second absorption layer 2400 and transferred to the pixel electrode 255 between portions of the pixel defining layer 260 of the transistor substrate TS. The bank layer 2600 may be patterned to have openings in regions radiated with laser light LS1. The second absorption layer 2400 may be exposed through the openings of the patterned bank layer 2600. The transfer layer 2500 may be formed on the bank layer 2600 and some or all portions of the second absorption layer 2400 which are exposed through the openings. The organic matter of the transfer layer 2500 formed or disposed on the second absorption layer 2400 may be sublimated in a substantially vertical direction by the bank layer 2600, which may be formed or disposed on both sides of each opening and transferred to the pixel electrode 255 of the transistor substrate TS.

The bank layer 2600 may be made of, but not limited to, silicon oxide (SiOx) or silicon nitride (SiNx).

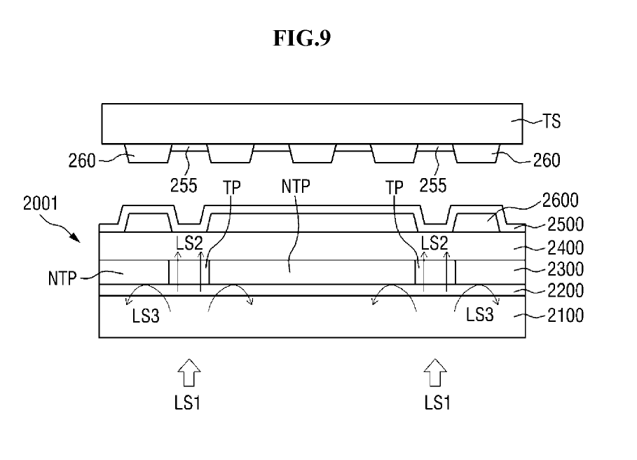

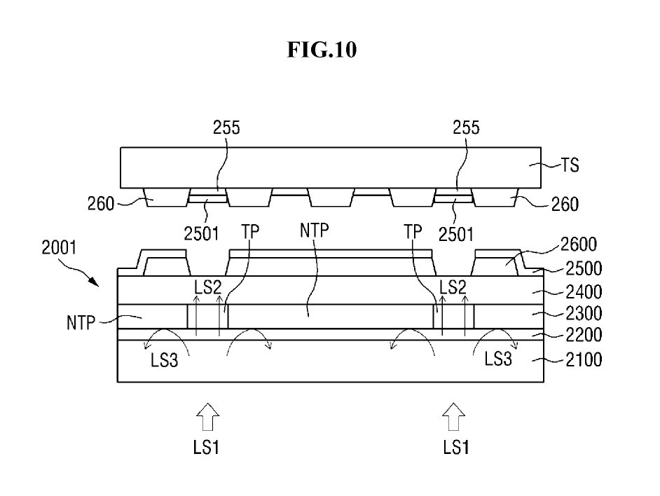

FIGS. 9 and 10 are views mimetically illustrating a process of forming an organic layer on a transistor substrate using an optical mask according to an exemplary embodiment of the present invention.

Referring to FIGS. 9 and 10, transmitting windows TP may be formed in regions that overlap the openings of the patterned bank layer 2600. The laser light LS1 may be radiated only to the regions overlapping the openings, thereby forming the transmitting windows TP in the regions overlapping the openings. As described above, only laser light LS2 that transmits through a light transmittance variable layer 2300 may be supplied to the second absorption layer 2400. The organic matter of the transfer layer 2500 in the openings may be sublimated by thermal energy generated from the second absorption layer 2400, and the openings of the bank layer 2600 may guide the organic matter to be sublimated in the substantially vertical direction. The organic matter may be intensively transferred only to the pixel electrode 255 between portions of the pixel defining layers 260 of the transistor substrate TS, in each of the regions overlapping the openings of the bank layer 2600. As a result, the organic layer 2501 may be formed.

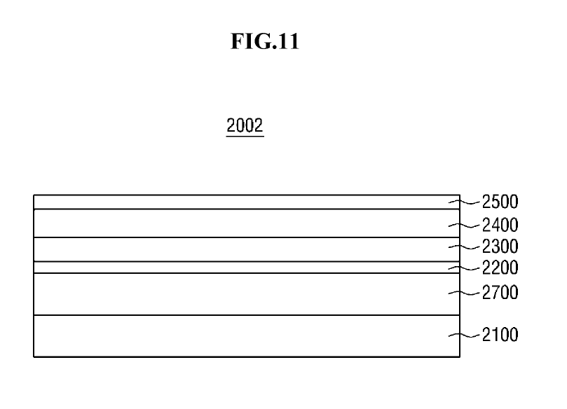

FIG. 11 is a mimetic cross-sectional view of an optical mask according to an exemplary embodiment of the present invention.

Referring to FIG. 11, the optical mask 2002 according to an exemplary embodiment may further include a thermal insulation layer 2700. The optical mask 2002 is different from the optical mask 2000 of FIG. 5 in that it further includes the thermal insulation layer 2700. The thermal insulation layer 2700 may prevent or impede diffusion of heat while laser light LS1 is reaching a first absorption layer 2200. For example, the thermal insulation layer 2700 may keep or insulate thermal energy sufficient to transfer organic matter of a transfer layer 2500 by preventing or impeding diffusion of thermal energy generated from the first absorption layer 2200. The thermal insulation layer 2700 may be made of a material having high light transmittance rate and low thermal conductivity. The thermal insulation layer 2700 may be made of a material having lower thermal conductivity than the first absorption layer 2200. For example, the thermal insulation layer 2700 may be made of any one of, but not limited to, titanium oxide, silicon oxide, silicon oxynitride, zirconium oxide, silicon carbide, silicon oxide (SiOx), silicon nitride (SiNx), and organic polymer.

In addition, the thermal insulation layer 2700 may be thicker than the first absorption layer 2200. As the thickness of the thermal insulation layer 2700 increases, the diffusion of heat to a base substrate 2100 may decrease.

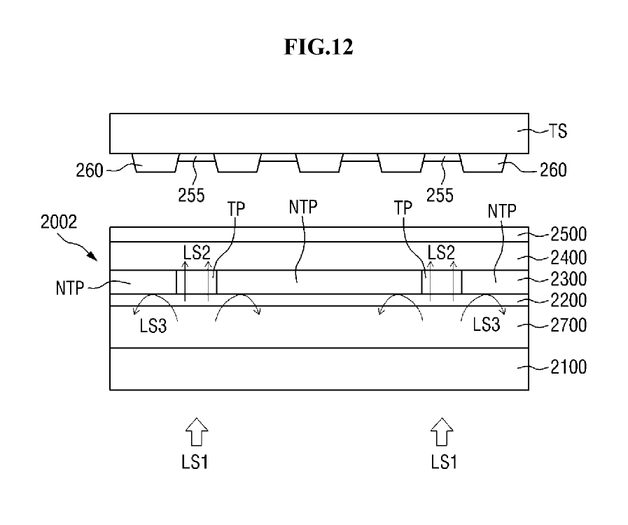

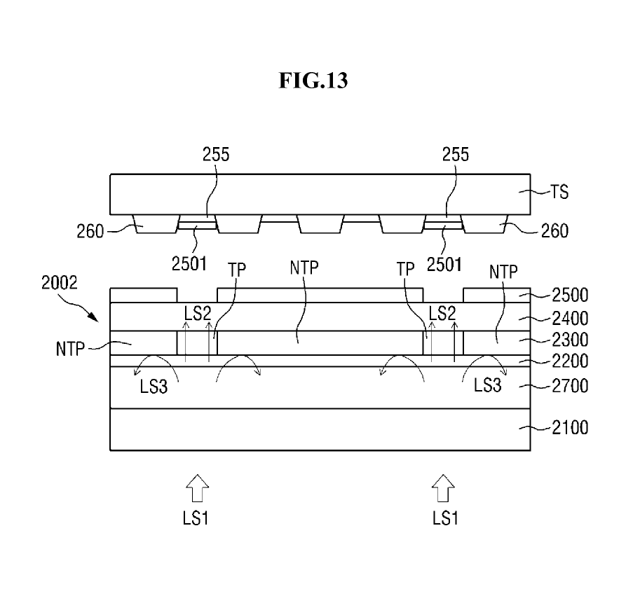

FIGS. 12 and 13 are views mimetically illustrating a process of forming an organic layer on a transistor substrate using an optical mask according to an exemplary embodiment of the present invention.

The process of FIGS. 12 and 13 is different from the process of FIGS. 6 and 7 in that the laser light LS1 may be selectively radiated to a light transmittance variable layer 2300 through the base substrate 2100, the thermal insulation layer 270, and the first absorption layer 2200.

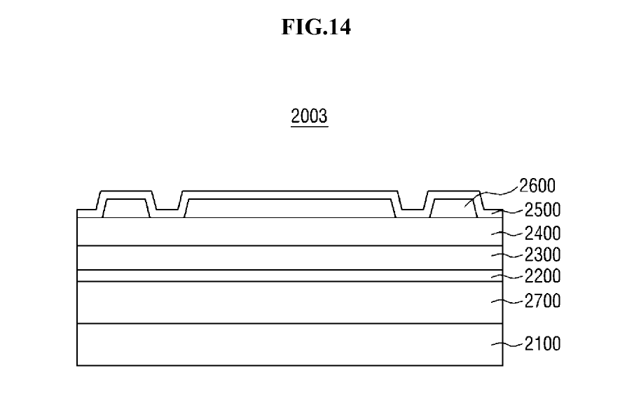

FIG. 14 is a mimetic cross-sectional view of an optical mask according to an exemplary embodiment of the present invention.

Referring to FIG. 14, the optical mask 2003 is different from the optical mask 2002 of FIG. 11 in that it further includes a patterned bank layer 2600 on a second absorption layer 2400.

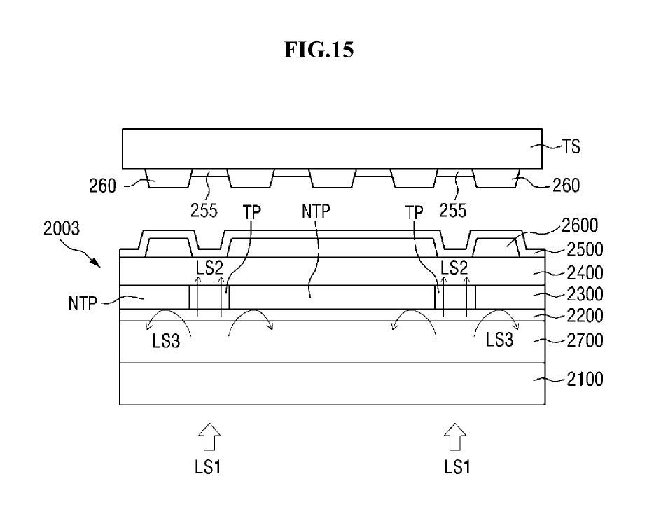

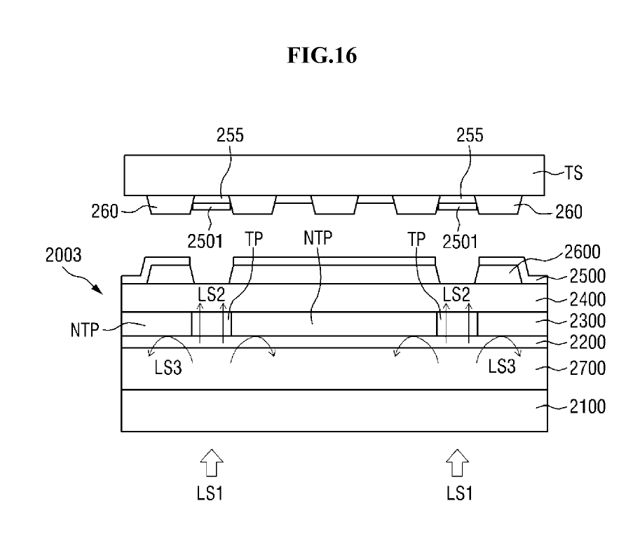

FIGS. 15 and 16 are views mimetically illustrating a process of forming an organic layer on a transistor substrate using an optical mask according to an exemplary embodiment of the present invention.

The process of FIGS. 15 and 16 is different from the process of FIGS. 13 and 14 in that transmitting windows TP are formed in regions overlapping openings of the patterned bank layer 2600 by radiating the laser light LS1 only to regions corresponding to the openings of the patterned bank layer 2600, that laser light LS2 reaches the second absorption layer 2400 through the transmitting windows TP, and that organic matter of a transfer layer 2500 in the openings is sublimated as the second absorption layer 2400 converts the laser light LS2 into thermal energy.

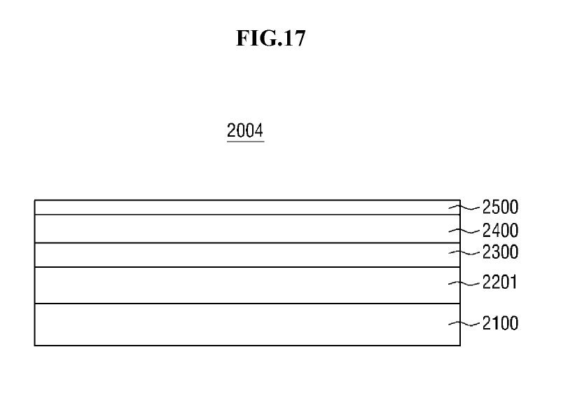

FIG. 17 is a mimetic cross-sectional view of an optical mask according to an exemplary embodiment of the present invention.

The optical mask 2004 of FIG. 17 is different from the optical mask 2000 of FIG. 5 in that a polymer layer 2201 is formed between a base substrate 2100 and a light transmittance variable layer 2300. Referring to FIG. 5, the optical mask 2000 includes the first absorption layer 2200 disposed between the base substrate 2100 and the light transmittance variable layer 2300. The polymer layer 2201 may be made of, but not limited to, a polymer (e.g., polyimide (PI)) having a high light transmittance rate.

The polymer layer 2201 may be a thermal insulation layer (e.g., the thermal insulation layer 2700 of FIG. 11) made of a light-transmitting polymer. For example, the light transmittance variable layer 2300 including paraffin wax and polydimethylsiloxane may have a light transmittance rate of 80% at a temperature of 55° C. or above because the melting point of paraffin wax is 53° C. as described above. If the polymer layer 2201 is made of polyimide, the light transmittance variable layer 2300 may turn transparent because polyimide absorbs approximately 25% of laser light having a wavelength of 808 nm. While the optical mask 2000 may make the light transmittance variable layer 2300 transparent using the first absorption layer 2200, the optical mask 2004 may make the light transmittance variable layer 2300 transparent using a polymer as a thermal insulation material. The polymer layer 2201 may prevent or impede thermal diffusion as well as supply heat to the light transmittance variable layer 2300. The polymer layer 2201 may be thicker than the first absorption layer 2200. The thickness of the polymer layer 2201 may be adjusted in view of material properties within a range in which thermal energy sufficient to thermally bleach the light transmittance variable layer 2300 may be transmitted to the light transmittance variable layer 2300.

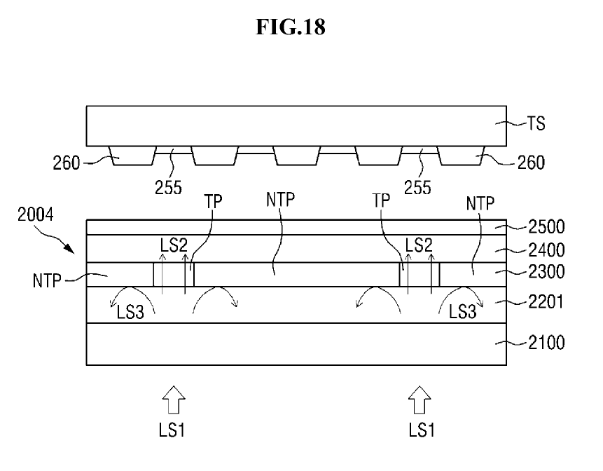

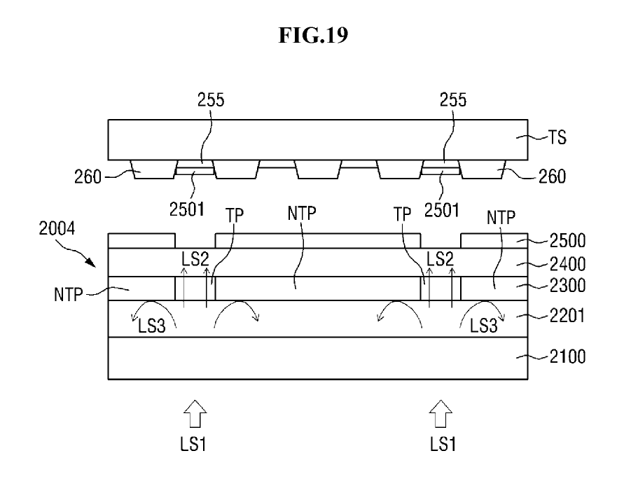

FIGS. 18 and 19 are views mimetically illustrating a process of forming an organic layer on a transistor substrate using an optical mask according to an exemplary embodiment of the present invention.

Referring to FIGS. 18 and 19, the polymer layer 2201 may absorb selectively radiated laser light LS1 to form the transmitting windows TP in the light transmittance variable layer 2300. Laser light L2 reaching a second absorption layer 2400 through the transmitting windows TP may be absorbed and converted into thermal energy by the second absorption layer 2400. A transfer layer 2500 may sublimate organic matter therein by absorbing the thermal energy generated from the second absorption layer 2400 and transferring the organic matter to the pixel electrode 255 of the transistor substrate TS.

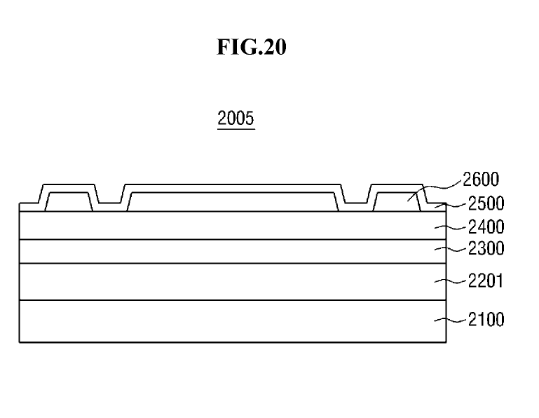

FIG. 20 is a mimetic cross-sectional view of an optical mask according to an exemplary embodiment of the present invention.

Optical mask 2005 of FIG. 20 is different from the optical mask 2004 of FIG. 17 in that a patterned bank layer 2600 formed on a second absorption layer 2400.

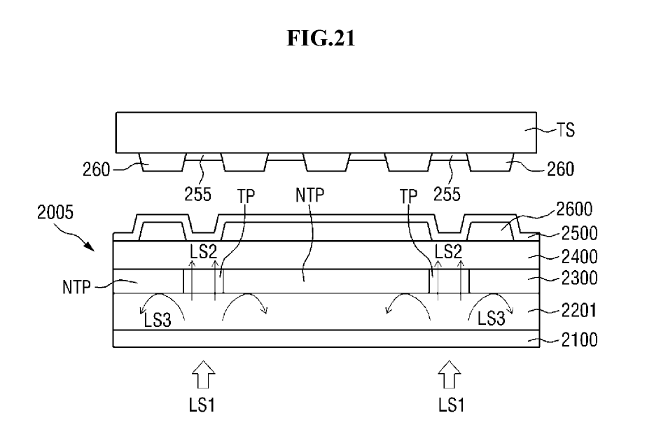

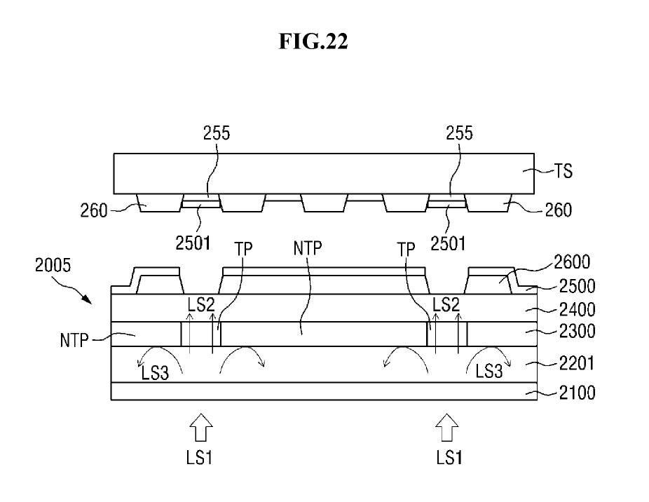

FIGS. 21 and 22 are views mimetically illustrating a process of forming an organic layer 2501 on a transistor substrate TS using the optical mask 2005 according to an exemplary embodiment of the present invention.

The process of FIGS. 21 and 22 is different from the process of FIGS. 18 and 19 in that thermal energy is generated from a polymer layer 2201 only in regions overlapping openings of the patterned bank layer 2600 by radiating laser light LS1 only to regions corresponding to the openings and that transmitting windows TP are formed in a light transmittance variable layer 2300 only in the regions overlapping the openings.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An optical mask comprising:
a light transmittance variable layer configured to be in a transparent state when thermal energy is generated, and to be in an opaque state when the thermal energy dissipates; and
a heat generation layer disposed on a first surface of the light transmittance variable layer, the heat generation layer configured to generate the thermal energy.

2. The optical mask of claim 1, further comprising:
a light-transmitting base substrate disposed on a surface of the heat generation layer; and
a light-to-heat conversion layer disposed on a second surface of the light transmittance variable layer, the light-to-heat conversion layer configured to convert light energy transmitted through the light transmittance variable layer into thermal energy.

3. The optical mask of claim 1, wherein the heat generation layer is a light-to-heat conversion layer configured to convert light energy into thermal energy, and comprises one of molybdenum (Mo), chrome (Cr), titanium (Ti), tin (Sn), tungsten (W), and alloys of the same.

4. The optical mask of claim 2, wherein the light-to-heat conversion layer comprises one of Mo, Cr, Ti, Sn, W, and alloys of the same.

5. The optical mask of claim 2, further comprising a thermal insulation layer disposed between the base substrate and the heat generation layer and configured to impede diffusion of the thermal energy generated from the heat generation layer.

6. The optical mask of claim 5, wherein the thermal insulation layer is comprises at least one of a silicon nitride, a silicon oxide, and a light-transmitting polymer having lower absorbance rate than the heat generation layer.

7. The optical mask of claim 1, wherein the light transmittance variable layer comprises at least one of paraffin wax and polydimethylsiloxane, the light transmittance variable layer configured to be in the transparent state at a melting point of the paraffin wax or polydimethylsiloxane.

8. The optical mask of claim 2, further comprising discontinuous bank patterns on the light-to-heat conversion layer, wherein the light-to-heat conversion layer is exposed between the discontinuous bank patterns.

9. The optical mask of claim 1, wherein the heat generation layer comprises a light-transmitting polymer.

10. The optical mask of claim 9, wherein the light-transmitting polymer is a polyimide.

11. An optical mask comprising:
a first absorption layer configured to convert light energy into thermal energy;
a light transmittance variable layer disposed on the first absorption layer, the light transmittance variable layer configured to be in a transparent state when thermal energy is generated, and to be in an opaque state when the thermal energy dissipates; and
a second absorption layer disposed on the light transmittance variable layer, the second absorption layer configured to convert light energy transmitted through the light transmittance variable layer into the thermal energy,
wherein the second absorption layer is thicker than the first absorption layer.

12. The optical mask of claim 11, wherein the light transmittance rate of the first absorption layer is 90% or more, and the light absorption rate of the second absorption layer is 95% or more.

13. A method to transfer laser, the method comprising:
radiating light to transfer at least some of organic matter of a transfer layer to a target substrate;
converting at least some of energy of the radiated light transmitted through a light-to-heat conversion layer disposed on a first surface of a light transmittance variable layer to a thermal energy; and
generating the thermal energy by a heat generation layer disposed on a second surface of the light transmittance variable layer,
wherein the light transmittance variable layer is configured to be in a transparent state when the thermal energy is generated, and to be in an opaque state when the thermal energy dissipates, and
wherein the transfer layer is disposed on the light-to-heat conversion layer.

14. The laser transfer method of claim 13, wherein the light-to-heat conversion layer has a rectangular thermal energy profile without Gaussian tails.

15. The laser transfer method of claim 13, wherein the organic matter comprises organic matter of one or more of an organic light-emitting layer (EML), an organic matter of a hole injection layer (HIL), an organic matter of a hole transport layer (HTL), an organic matter of an electron injection layer (EIL), and an organic matter of an electron transport layer (ETL) included in an organic light-emitting display device.

16. The laser transfer method of claim 13, wherein a transparent transmitting window is disposed on a first region of the light transmittance variable layer overlapping regions radiated with the laser light, and a second region of the light transmittance variable layer overlapping regions not radiated with the laser light, the second region being opaque.
